(19) United States
(12) Patent Application Publication
(10) Pub. No.: US 2014/0224766 A1
(43) Pub. Date: Aug. 14, 2014

(54) Groove Design for Retaining Ring

(71) Applicant: Taiwan Semiconductor Manufacturing Company, Ltd., (US)

(72) Inventors: Yi-Min Chou, Hsin-Chu (TW); Chia-Lin Hsueh, Zhubei City (TW)

(73) Assignee: Taiwan Semiconductor Manufacturing Company, Ltd., Hsin-Chu (TW)

(21) Appl. No.: 13/763,186

(22) Filed: Feb. 8, 2013

(51) Int. Cl. H01L 21/465

(52) U.S. Cl. CPC H01L 21/465
USPC 216/53; 156/345.14

(57) ABSTRACT

An embodiment includes an annular ring having an intended direction of rotation, the ring having a top side and a bottom side, and further having an outer perimeter and an inner perimeter, and a multitude of grooves in the bottom side of the ring, each groove having an entry point at the outer perimeter connected to an exit point at the inner perimeter creating an opening through the ring, and each groove oriented so that an angle of each groove is obtuse, wherein the angle of each groove is defined as an angle between a first ray having an initial point at the entry point and having a direction along the groove towards the exit point, and a second ray having an initial point at the entry point and having a direction tangent to the annular ring at the entry point and opposite the intended direction of rotation.

### BACKGROUND

Generally, semiconductor devices comprise active components, such as transistors, formed on a substrate. Any number of interconnect layers may be formed over the substrate connecting the active components to each other and to outside devices. The interconnect layers are typically made of low-k dielectric materials comprising metallic trenches/vias.

As the layers of a device are formed, it is sometimes necessary to planarize the device. For example, the formation of metallic features in the substrate or in a metal layer may cause uneven topography. This uneven topography creates difficulties in the formation of subsequent layers. For example, uneven topography may interfere with the photolithographic process commonly used to form various features in a device. It is, therefore, desirable to planarize the surface of the device after various features or layers are formed.

One commonly used method of planarization is via chemical mechanical polishing (CMP). Typically, CMP involves placing a wafer in a carrier head, wherein the wafer is held in place by a retaining ring. The carrier head and the wafer are then rotated as downward pressure is applied to the wafer against a polishing pad. A chemical solution, referred to as a slurry, is deposited onto the surface of the polishing pad to aid in the planarizing. Ideally, the retaining ring comprises a multitude of grooves to facilitate the even distribution of the slurry over the wafer surface. When retaining rings without any grooves are used during CMP, the resulting wafers tend to suffer topographical unevenness due to irregular slurry disposition. Thus, the surface of a wafer may be planarized using a combination of mechanical (the grinding) and chemical (the slurry) forces.

As part of the planarization process, it is also necessary to condition the polishing pad using a pad conditioner. A typical pad conditioner comprises an array of abrasive particles bonded to a substrate. Conditioning removes accumulated debris build-up and excess slurry from the pad. Conditioning also texturizes the surface of the pad. The polishing pad is typically made of smooth compounds such as rubber. Therefore, it is desirable to condition the pad to provide a rougher surface for better slurry distribution and polishing.

However, this conditioning process can lead to damaged wafers. The abrasive particles of the pad conditioner can become dislodged from the conditioner and get lodged in the retaining ring. When a wafer is then polished using that retaining ring, the abrasive particles can cause peeled edges, scratches, or breaks in the wafer. This problem is compounded by the grooves of a typical retaining ring because the grooves facilitate the movement of the abrasive particles to the inner perimeter of the retaining ring towards the wafer. However, as the grooves are a part of a retaining ring's design, a new design for the orientation of grooves is necessary.

### BRIEF DESCRIPTION OF THE DRAWINGS

For a more complete understanding of the present embodiments, and the advantages thereof, reference is now made to the following descriptions taken in conjunction with the accompanying drawings, in which:

FIG. 1 shows a perspective view of a CMP station according to an embodiment of the present invention;

FIGS. 2 and 3 show top-down views of a CMP station according to an embodiment of the present invention;

FIGS. 4 and 4A are a top down views of a CMP station showing the design for a retaining ring according to an embodiment;

FIGS. 5, 5A, 5B, and 5C are top down views of a CMP station showing the movement paths of abrasive particles according to an embodiment;

FIG. 6 is a bottom view of a retaining ring according to an embodiment; and

FIG. 7 show two wafers polished using a retaining ring as is known in the art and a retaining ring according to an embodiment.

### DETAILED DESCRIPTION OF ILLUSTRATIVE EMBODIMENTS

The making and using of the present embodiments are discussed in detail below. It should be appreciated, however, that the present disclosure provides many applicable inventive concepts that can be embodied in a wide variety of specific contexts. The specific embodiments discussed are merely illustrative of specific ways to make and use the disclosed subject matter, and do not limit the scope of the different embodiments.

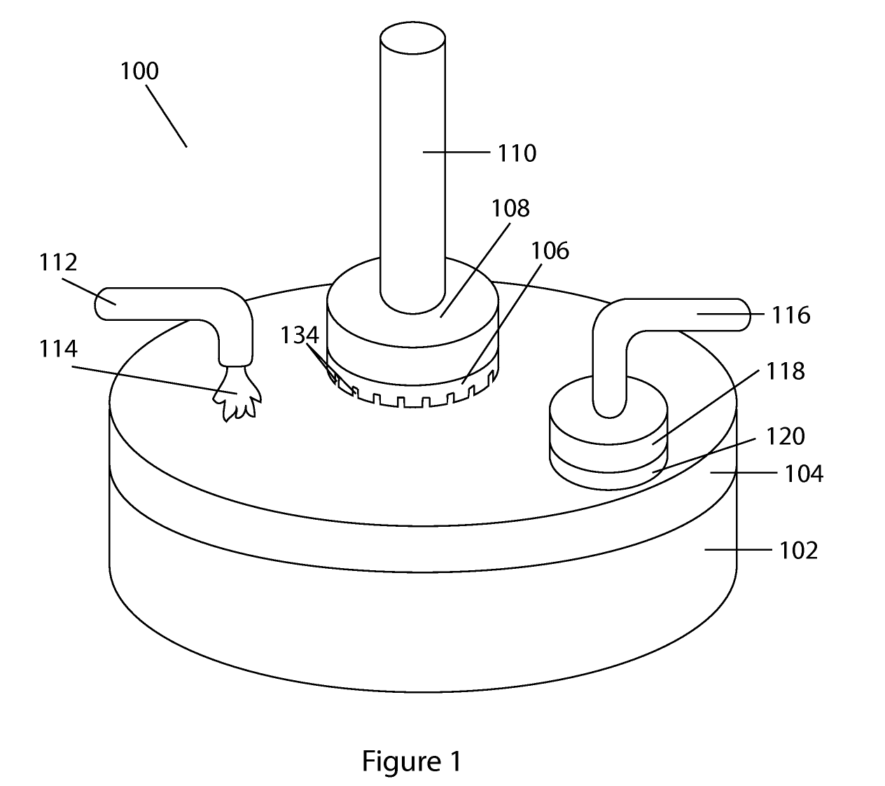

FIG. 1 shows a perspective view of a portion of a polishing station 100, which may be used in a CMP process according to one embodiment of the present invention. Polishing station 100 includes a rotating platen 102 over which a polishing pad 104 has been placed. A rotating carrier 110 is placed over the polishing pad. The rotating carrier 110 includes a carrier head 108 and a retaining ring 106. A wafer (not shown) may be placed within carrier head 108 and is held by retaining ring 106. Retainer ring 106 is generally annular in shape with a hollow center. The wafer is placed in the hollow center of retainer ring 106 such that the retaining ring 106 holds the wafer in place during CMP. The wafer is positioned so that the surface to be planarized faces downward towards polishing pad 104. Carrier 110 applies downward pressure and causes the wafer to come in contact with polishing pad 104.

A slurry arm 112 deposits a slurry 114 onto polishing pad 104. The rotating movement of platen 102 causes the slurry 114 to be distributed over the wafer through a multitude of grooves 134 in retaining ring 106. The composition of the slurry depends on the type of material on the wafer surface undergoing CMP. For example, oxide file has a higher hardness than copper film; therefore oxide CMP slurries composition typically has a higher remove rate than copper CMP slurries.

Grooves 134 create an opening extending from the outer perimeter of retaining ring 106 to the wafer, allowing for the even distribution of slurry 114 over the wafer. Ideally, the grooves may have a width less than about 3 mm and a depth of about 3 mm. It is contemplated in other embodiments to have grooves with different dimensions. The grooves are oriented so that slurry 114 may be distributed evenly to the wafer while any abrasive particles are kept away from the wafer.

A pad conditioner arm 116 moves a rotating pad conditioning head 118 in a sweeping motion across a region of the polishing pad 104. Conditioning head 118 holds a pad conditioner 120 in contact with polishing pad 104. Pad conditioner 120 typically comprises a substrate over which an array of abrasive particles, such as diamonds, is bonded using, for example, electroplating. Pad conditioner 118 removes built-up wafer debris and excess slurry from polishing pad 104. Pad conditioner 118 also acts as an abrasive for polishing pad 104 to create an appropriate texture against which the wafer may be properly planarized.

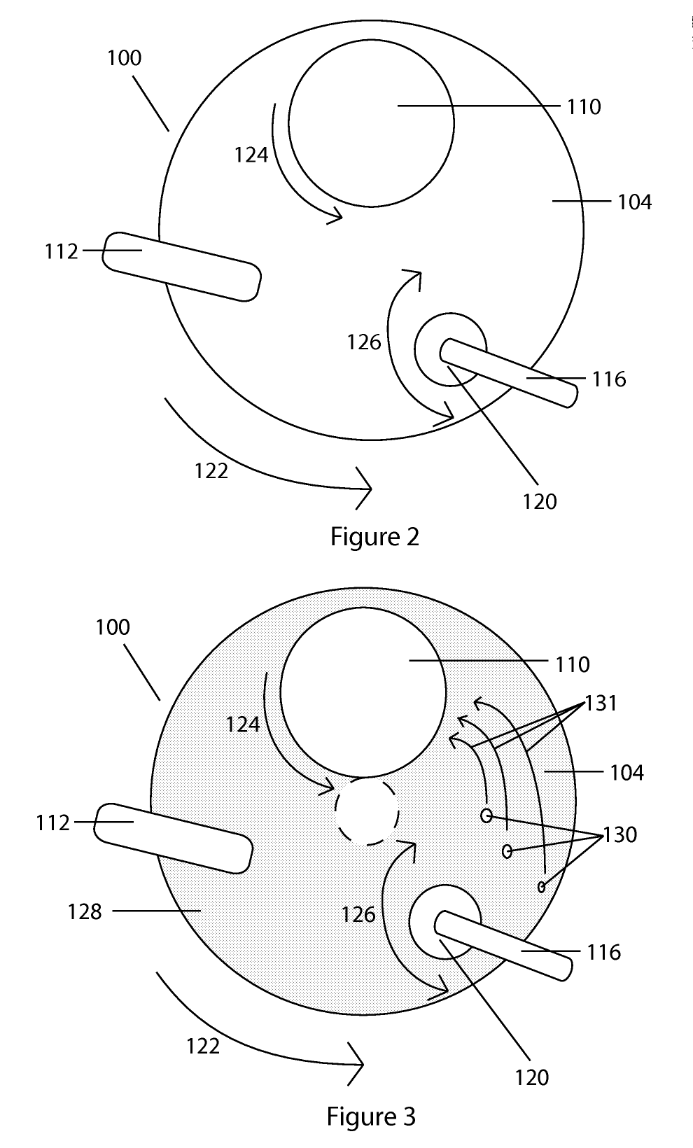

Now referring to FIG. 2, a top-down view of polishing station 100 is shown. Platen 102 rotates polishing pad 104 in the counter-clockwise direction indicated by arrow 122. Carrier 110 rotates independently in the same counter-clockwise direction as shown by arrow 124. Pad conditioning arm 116 sweeps pad conditioner 120 in an arc as indicated by arc 126. As platen 102 rotates, different areas of polishing pad 104 are fed under carrier 110 and used to planarize the wafer. Simultaneously, platen 102 moves areas of polishing pad 104 that were previously in contact with the wafer to pad conditioner 120. Pad conditioning arm 116 sweeps pad conditioner 120 across the areas previously used to polish the wafer and conditions these areas. The platen 102 then moves these areas back under carrier 110 and the wafer. In this manner, the polishing pad may be simultaneously conditioned while a wafer is polished.

The range of arc 126 corresponds with the size of carrier 110. For example, carrier 110 may be 12 inches in diameter, rotating an inch inward from the perimeter of platen 102. Accordingly, arc 126 would extend from the perimeter of platen 102 to a distance of at least 13 inches inward from that perimeter. This ensures that any portion of polishing pad 104 that may contact carrier 110, and consequentially the wafer, is conditioned appropriately. One skilled in the art would recognize that the numbers given in this paragraph are exemplary. The actual dimensions of carrier 110 and the corresponding range of arc 126 may vary depending on the dimensions of the wafer being polished.

FIG. 3 shows the same polishing station 100 as FIGS. 1 and 2. Region 128 corresponds with the portions of polishing pad 104 that come in contact with carrier 110 and pad conditioner 120. Abrasive particles 130 may become dislodged from pad conditioner 120 and fall off onto Region 128. Typically, particles 130 may be between 100 g and 250 g in size, but they have been enlarged in FIG. 3 for illustrative purposes. Arrows 131 indicate potential movement paths for particles 130. Particles 130 are transported via rotating platen 102 to carrier 110 where they could potentially be lodged in retaining ring 106. If these abrasive particles 130 become lodged in retaining ring 106, they may then cause scratches, peeled edges, and breaks in the wafer.

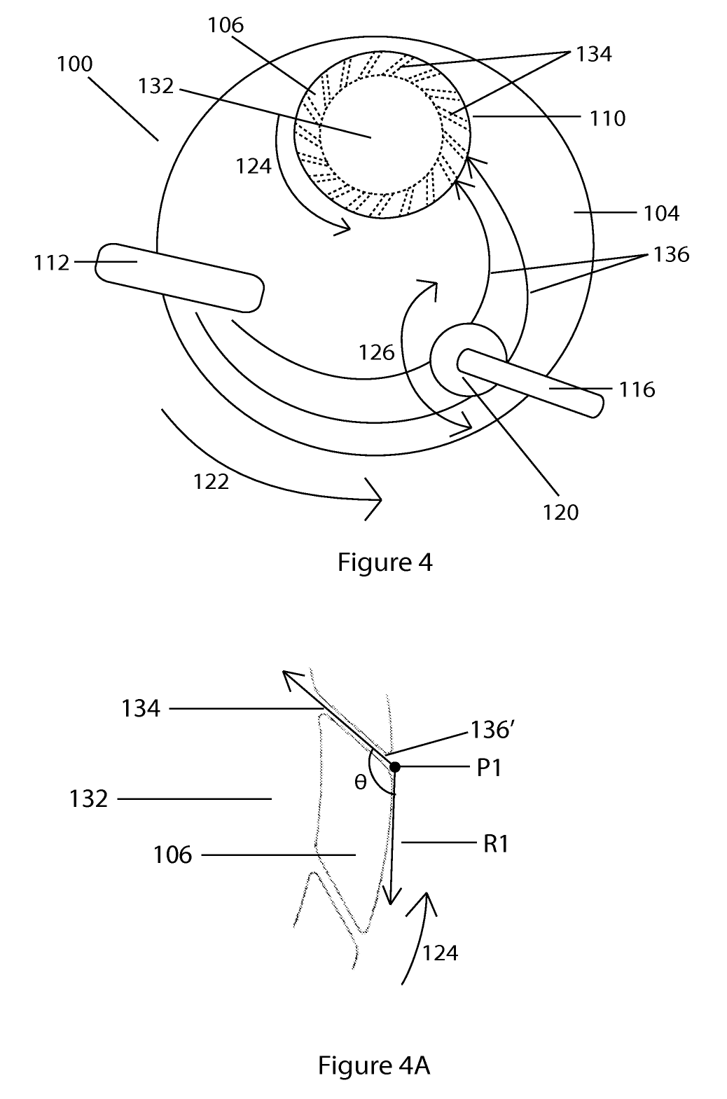

FIG. 4 shows a top view of the same polishing station 100 as FIGS. 1-3. Retaining ring 106 holding a wafer 132 is shown in phantom in carrier 110. Slurry 114 is evenly distributed onto wafer 132 through a multitude of grooves 134 in retaining ring 106. Arrows 136 indicate various paths of slurry 114 as it is distributed through grooves 134 over wafer 132. Grooves 134 are shown in ghost in FIG. 4 for illustrative purposes; grooves 134 contact the top surface of polishing pad 104 and may not be visible from a top view of polishing station 100.

FIG. 4A shows a magnified view of FIG. 4 illustrating slurry 114's path through a particular groove 134 in retaining ring 106. Retaining ring 106 is rotating in the counter clockwise direction indicated by arrow 124. The angle of groove 134 is denoted by angle θ. Angle θ is defined as the angle between a path of entry for slurry 114, marked as ray 136′, and a ray R1. Ray 136′ has an initial point at the point of entry into groove 134, point P1. Ray 136′ further has a direction following the path of slurry through groove 134 towards the wafer. Ray R1 has an initial point at P1 and is tangent to retaining ring 106. Ray R1 has a direction that is opposite the direction of retainer ring 106's rotation. In FIG. 4A, retaining ring 106 is moving upwards at P1, and so accordingly ray R1 is pointed in a downward direction. One skilled in the art would recognize that if retaining ring 106 were rotating downward at P1, ray R1 would be oriented in the opposite direction, upward. According to an embodiment of this invention, θ is an obtuse angle. It has been noted that orienting each groove in retaining ring 106 at this angle significantly reduces the amount of damage caused by abrasive particles 130 to wafer 132. While not limiting the present disclosure to any particular theory of operation, it is believed that by orienting the grooves 134 in a direction opposite the direction of rotation, particles 130 are much likely to enter into and become lodged in grooves 134.

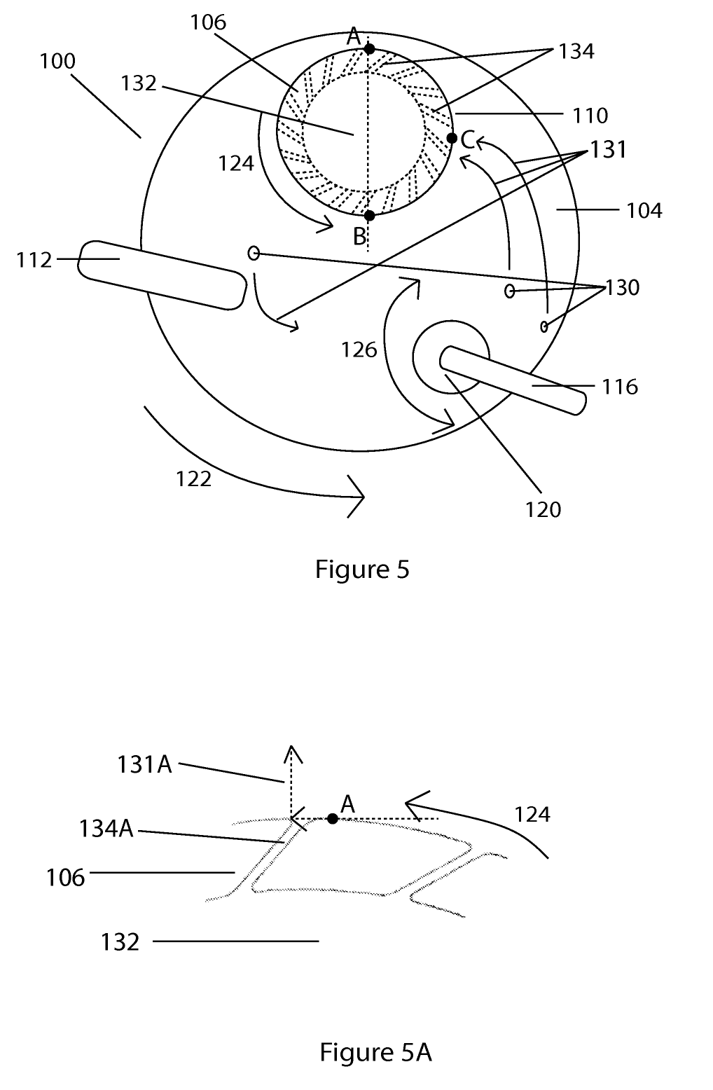

FIG. 5 shows the same polishing station 100. Wafer 132 and retaining ring 106, comprising grooves 134, are shown in ghost. Points A, B, and C are three points where abrasive particles 130 may come in contact with and become lodged in retaining ring 106. Arrows 131 indicate the paths of these abrasive particles 130. A line AB, intersecting points A and B, would bisect carrier 110. It is unlikely for abrasive particles become lodged in retaining ring 106 to the left of line AB. This is because the rotation of platen 102, indicated by arrow 122, would be moving particles 130 away from carrier 110 at those points. Point C may be any point along retaining ring 106 and the arc segment formed by connecting Points A and B.

FIGS. 5A and 5B show a magnified view of carrier 100 at points A and B respectively. Grooves 134A and 134B correspond to particular grooves 134 at points A and B respectively. At these points, particles 130 move tangentially to retaining ring 106 as indicated by arrows 131A and 131B. Particles 130 are unlikely to enter grooves 134A or 134B because of their movement paths, and therefore particles 130 that come in contact with carrier 110 at these points are unlikely to lead to wafer defects.

FIG. 5C shows a magnified view of carrier 100 at point C. Arrow 124 indicates the rotation direction of retaining ring 106. Arrows 131C indicate potential movement paths of abrasive particles 130 traveling into groove 134C, wherein groove 134C corresponds to a particular groove 134 at point C. Distance W1 represents the width of groove 134C in a typical embodiment. Distance W1 may vary based on the size of carrier 110 and the wafer, but may be less than about 3 mm.

Distance W2 correlates to the area of retaining ring 106 around groove 134C that contains the worst-case-scenario of particle 130 movements. Distance W2 may be slightly wider than or about the same as distance W1. Particles 130 moving outside the range of W2 will deflected by the outer wall of retaining ring 106 and not enter groove 134C. Due to the orientation of groove 134C, particles 130 that do enter groove 134C will be kept to the outer perimeter of retaining ring 106. These movements are shown by arrows 131C. Any particles 130 that enter groove 134A will be deflected off the inner wall of groove 134C and remain along the outer perimeter of retaining ring 106 where the particles 130 are less likely to damage the wafer. The orientation of groove 134C significantly reduces the amount of particles 130 being lodged on the inner perimeter of retaining ring 106 thereby reducing the number of wafer defects caused by abrasive particles 130.

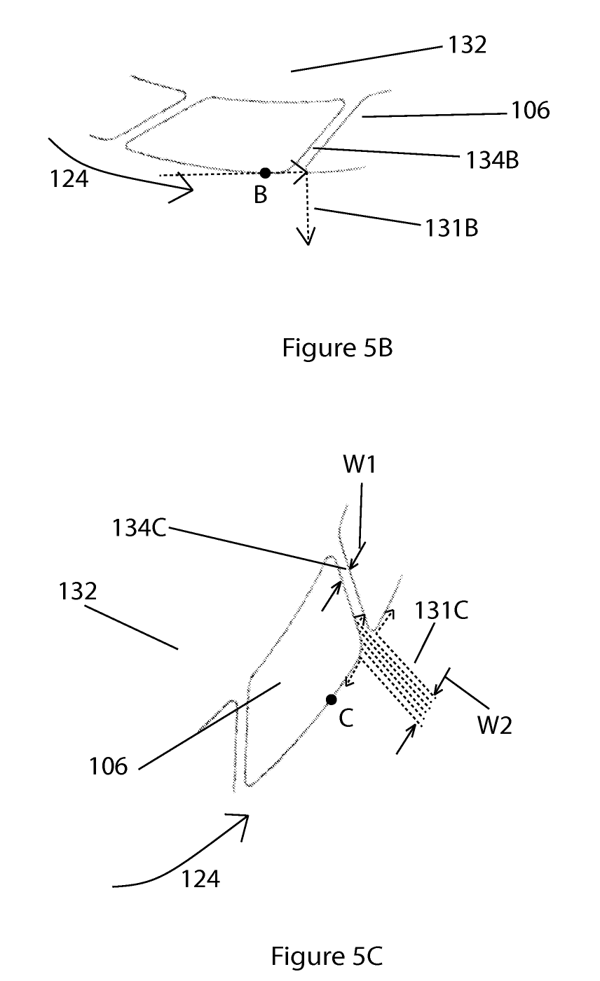

FIG. 6 shows an exemplary configuration of a retaining ring according to the present invention. Retaining ring 106 has 18 grooves spaced every 20° around retaining ring 106. Each groove 134 is oriented so that the angle of each groove is about 135°. Retaining ring 106 is designed to be rotated in the counter-clockwise direction indicated by arrow 124. It has been observed that this configuration minimizes the amount of wafer damaged caused by lodged particles in retaining ring 106. It is, however, contemplated in other embodiments to have a differing number of grooves spaced at different points along a retaining ring. It is also contemplated in other embodiments to orient the grooves to have a different angle between 91° and 179°. Furthermore, it is contemplated to orient the grooves in the opposite direction than what is illustrated in FIG. 6 for retaining rings designed to be rotated in a clockwise direction.

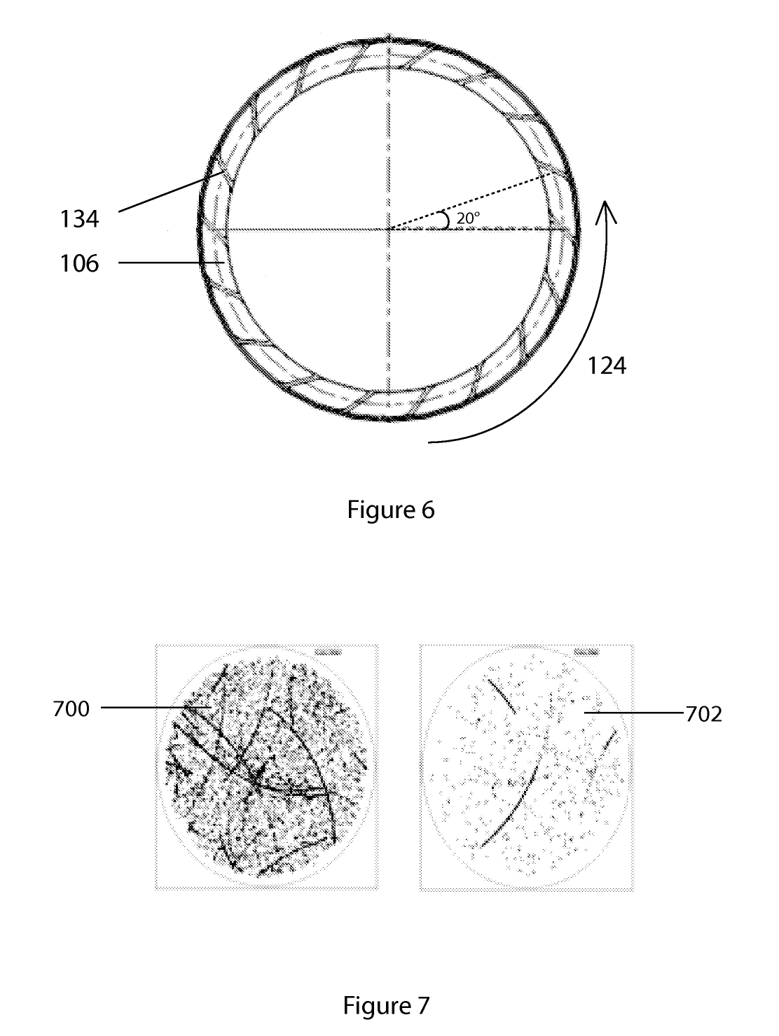

FIG. 7 show experimental data comparing the wafer scratches resulting from groove configurations as known in the art and the groove configuration show in FIG. 6. For wafer 700, a retaining ring comprising grooves as is known in the current art was used during CMP. For wafer 702, a retaining ring comprising grooves oriented according to FIG. 6 was used. As part of the experiment, 1000 abrasive particles were intentionally deposited over the polishing station of both wafers during CMP. The markings on both figures indicate any scratches, breaks, or peeling sustained by each wafer after CMP. Comparing the two figures, it is clear that the damage sustained by the wafer 702 was significantly less than the damage of the wafer 700.

It has also been noted that the present embodiment does not significantly impact the even distribution of the slurry onto a wafer. The removal rate of a wafer is defined as the thickness of the wafer prior to polish minus the thickness of the wafer after polish. In experiments conducted, the removal rate on wafers polished using the present embodiment was reduced by only 10%, which is within tolerance levels for removal rates. Furthermore, the post-polishing profiles examining the evenness of a wafer after CMP was substantially similar between wafers polished using the present embodiment versus what is known in the art.

Although the present embodiments and their advantages have been described in detail, it should be understood that various changes, substitutions and alterations can be made herein without departing from the spirit and scope of the disclosure as defined by the appended claims.

Moreover, the scope of the present application is not intended to be limited to the particular embodiments of the process, machine, manufacture, composition of matter, means, methods and steps described in the specification. As one of ordinary skill in the art will readily appreciate from the disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

1. A retaining ring comprising:
an annular ring having an intended direction of rotation, the ring having a top side and a bottom side, and the annular ring further having an outer perimeter and an inner perimeter; and
a multitude of grooves in the bottom side of the ring, each groove having an entry point at the outer perimeter connected to an exit point at the inner perimeter creating an opening through the annular ring, and each groove further oriented so that an angle of each groove is obtuse, wherein the angle of each groove is defined as an angle between:
a first ray having an initial point at the entry point and having a direction along the groove towards the exit point; and
a second ray having an initial point at the entry point and having a direction tangent to the annular ring at the entry point and opposite the intended direction of rotation.

2. The retaining ring of claim 1, wherein the grooves do not penetrate the top side of the annular ring.

3. The retaining ring of claim 1, wherein each groove has a depth of about 3 mm.

4. The retaining ring of claim 1, wherein the angle of each groove is about 135 degrees.

5. The retaining ring of claim 1, wherein eighteen grooves are positioned equidistantly around the annular ring.

6. The retaining ring of claim 1, wherein each groove is substantially uniform in width.

7. The retaining ring of claim 1, wherein each groove has a width of less than about 3 mm.

8. The retaining ring of claim 1, wherein the annular ring is substantially uniform in width.

9. A chemical mechanical polishing station comprising:
a rotating platen;
a polishing pad placed over the rotating platen;
a rotating carrier comprising a retaining ring configured to hold a wafer; the retaining ring comprising:
a circular ring having a top side and a bottom side, the ring further having an inner perimeter and an outer perimeter;
a multitude of grooves in the bottom side of the ring, wherein each groove forms an opening at the outer perimeter connected to an opening at the inner perimeter, and wherein each groove is oriented at a slant; and wherein the carrier is further configured so that during each rotation of the carrier, for any ray having an initial point at center of the retaining ring, the rotation of the carrier causes the opening at the inner perimeter of a groove to move past the ray before the opening at the outer perimeter of the groove moves past the ray; and
a slurry arm configured to deliver a slurry onto the polishing pad through the grooves and onto a wafer.

10. The chemical mechanical polishing station of claim 9, further comprising a pad conditioning arm configured to sweep a pad conditioner over a portion of the polishing pad.

11. The chemical mechanical polishing station of claim 10, wherein the pad conditioner comprises an array of diamonds bonded over a substrate.

12. The chemical mechanical polishing station of claim 9, wherein an obtuse angle formed between the slant of a groove and a line tangent to the outer perimeter of the retaining ring at the groove is about 135 degrees.

13. The chemical mechanical polishing station of claim 9, wherein the retaining ring comprises eighteen grooves positioned at uniform intervals along the ring.

14. The chemical mechanical polishing station of claim 9, wherein each groove is less than about 3 mm in width.

15. The chemical mechanical polishing station of claim 9, wherein the grooves do not extend through the top side of the ring.

16.-20. (canceled)

21. A retaining ring comprising:
an annular ring;
a groove in the annular ring, wherein the groove is configured to receive a slurry from an entry point of the groove at an outer perimeter of the annular ring, and wherein the groove is oriented to have an obtuse angle, wherein the obtuse angle is defined by:
a first ray parallel to a sidewall of the groove, the first ray having an initial point at the entry point and a direction towards an inner perimeter of the annular ring; and
a second ray tangent to the annular ring, the second ray having an initial point at the entry point tangent and a direction opposite an intended direction of rotation of the annular ring.

22. The retaining ring of claim 21, wherein the retaining ring is configured to distribute the slurry over a wafer held by the retaining ring, wherein the slurry is distributed through the groove.

23. The retaining ring of claim 21, wherein the groove is in a first surface of the retaining ring, wherein the first surface of the retaining ring is configured to be oriented downwards when the slurry is received by the groove.

24. The retaining ring of claim 23, wherein the groove does not penetrate a second surface of the retaining ring opposite the first surface.

25. The retaining ring of claim 21, wherein the obtuse able is about 135 degrees, wherein the groove has a depth of about 3 mm, and wherein the groove has a width less than about 3 mm.
